(19) United States
(12) Patent Application Publication
(10) Pub. No.: US 2007/0045634 A1
(43) Pub. Date: Mar. 1, 2007

(54) Light emitting diode device

(75) Inventor: Ga-Lane Chen, Fremont, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Chen City (TW)

(21) Appl. No.: 11/414,599

(22) Filed: Apr. 28, 2006

(30) Foreign Application Priority Data
Aug. 26, 2005 (TW) 094129218

(51) Int. Cl. H01L 33/00

(52) U.S. Cl. 257/79

(57) ABSTRACT

A light emitting diode device includes a main substrate, a reflective layer, a joint layer, a light emitting diode layer and a diffusing layer stacked in turn from bottom to top, a material of the main substrate is silicon, a material of the reflective layer is metal alloy, the diffusing layer is scattered with nano silicon dioxide particles. A method for manufacturing the light emitting diode surface device is also provided.

### CROSS REFERENCE

This application relates to a contemporaneously filed application having the same title, the same applicant and the same assignee with the instant application.

### TECHNICAL FIELD

The present invention relates to a light source and a method for manufacturing the same, in particular, to a light emitting diode device and a method for manufacturing the same.

### BACKGROUND

Light emitting diodes (LED) is a solid semiconductor element, which can be used in a wide variety of devices, for example, optical displays, traffic lights, data storage devices, communication devices, illumination devices, and medical devices.

It is known to all that, when a current of only 2˜3 volt is introduced to an LED, two separate carriers—electrons with negative electric charge and holes with positive electrical charge—are produced. When the two carriers recombine with each other, extra energy is produced and then releases at a photon shape, thus the LED illuminates. For different materials used therein, energy levels of electrons and holes are different, which can affect extra energy and wavelength of light produced during the recombination of electrons and holes, thus different colors of red, green, blue etc will be displayed.

In an LED device, there is a transparent substrate and an LED stack attached thereto. Most of the transparent substrates are made from III-V group compound semiconductor materials in Periodical Table of Elements. III-V group compound semiconductor materials are combination of group-III element, i.e., boron (B), aluminum (Al), gallium (Ga), indium (In) or thallium (Ta), and group-V element, i.e., nitrogen (N), phosphorus (P), arsenic (As), antimony (Ti) or bismuth (Bi), such as GaAs, InP, GaN or GaAsP etc. Those III-V group compound semiconductor materials have properties of high frequency, radiation resistant and high insulated, and are widely used in LED field.

However, the LED has a narrow visual angle, when seen from a visual angle of 120 degrees, it takes image distortion phenomenon. Furthermore, the transparent substrate also has disadvantages of low heat transmission, heat produced by LED will not be dispersed efficiently, thus LED of those kind can only be used as component with low power, which restrict further application of LED.

Therefore, a heretofore-unaddressed need exists in the industry to address the aforementioned deficiencies and inadequacies.

### SUMMARY

In a preferred embodiment, a light emitting diode surface device is provided, which includes a main substrate, a reflective layer, a joint layer, a light emitting diode layer and a diffusing layer stacked in turn from bottom to top, a material of the main substrate is silicon, a material of the reflective layer is metal alloy, the diffusing layer is scattered with nano silicon dioxide particles.

In a second preferred embodiment, a method for manufacturing the light emitting diode surface device is also provided, which includes the following steps: providing a assist substrate and a main substrate, with a material of the main substrate being silicon; forming a light emitting diode layer on the assist substrate; forming a reflective layer on the main substrate, with a material of the reflective layer being metal alloy; forming a joint layer on the reflective layer; joining the reflective layer and the light emitting diode layer together via the joint layer; removing the assist substrate; and depositing a diffusing layer on the light emitting diode layer, which being scattered with nano silicon dioxide particles.

### BRIEF DESCRIPTION OF THE DRAWINGS

Many aspects of the present light emitting diode device and method for manufacturing the same can be better understood with reference to the following drawings. The components in the drawings are not necessarily to scale, emphasis instead being placed upon clearly illustrating the principles of the present light emitting diode device and method for manufacturing the same. Moreover, in the drawings, like reference numerals designate corresponding parts throughout the several views.

FIG. 1 is a schematic view of a light emitting diode device of the preferred embodiment.

FIG. 2A˜FIG. 2E schematicly illustrate a method for manufacturing the light emitting diode device of FIG. 1.

FIG. 3 is a schematic view showing illuminate principle of light emitting diode device of FIG 1.

FIG. 4 is a luminance-current contrast chart of light emitting diode device of FIG. 1 and typical LED.

FIG. 5 is a schematic view showing heat dissipation principle of light emitting diode device of the preferred embodiment.

### DETAILED DESCRIPTION

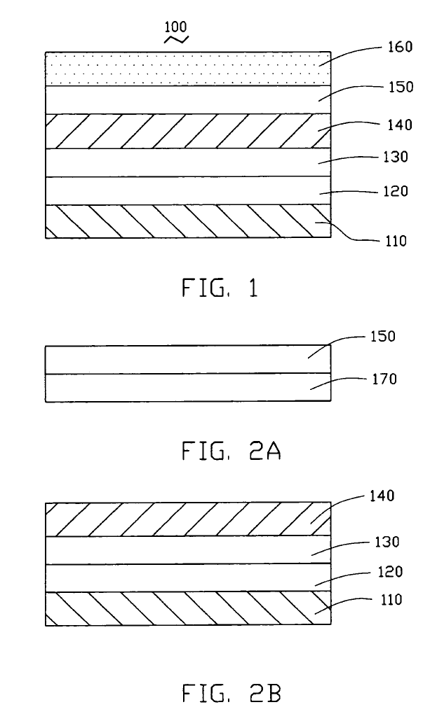

Referring to FIG. 1, a light emitting diode (LED) device 100 includes a main substrate 110, a transparent layer 120, a reflective layer 130, a joint layer 140, an LED layer 150 and a diffusing layer 160 stacked in turn from bottom to top.

A material of the main substrate 110 is silicon, with surface roughness of 0.1˜0.3 nanometers. A material of the transparent layer 120 is silicon dioxide (SiO₂). The transparent layer 120 has a thickness in the range from 5 to 20 nanometers. The transparent layer 120 is formed by heat oxidation or reactive sputtering deposition method.

A material of the reflective layer 130 is alloy AuX, AlY or AgZ, X represents Be, Li, Ag or Cu, Y represents Cu, Be or Mg, Z represents Be, Li or Al. The reflective layer 130 has a thickness in the range from 10 to 200 nanometers, preferably 20 to 50 nanometers, and also has a reflectivity of above 90 percent.

A material of the joint layer 140 is metal materials with high conductivity, such as Au, Al or Ag, with a thickness of 5˜20 nanometers. The diffusing layer 160 has a thickness in the range from 100 to 500 nanometers. The diffusing layer 160 is scattered with nano silicon dioxide (SiO₂) particles. The SiO₂ particles have an average particle size in the range from 2 to 20 nanometers, preferable 5 to 10 nanometers. The diffusing layer 160 is configured for scattering light beams by nano particles, thus get a wide range of light distribution.

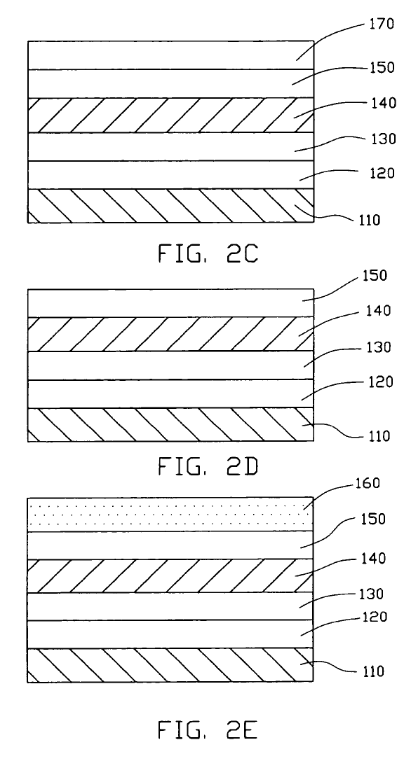

FIGS. 2A˜2E illustrate a method for manufacturing the light emitting diode device 100. Referring to FIG. 2A, an assist substrate 170 with a material of GaAs is provided. Other III-V group compound semiconductor materials such as GaAsP, AlGaAs etc can also be suitable. And then, an LED layer 120 is deposited uniformly on the assist substrate 110 by spin coating, uniform coating, pre-coating or chemical vapor depositing method.

Referring to FIG. 2B, a main substrate 110 with a material of silicon is provided. The main substrate 110 has a surface roughness in the range from 0.1 to 0.3 nanometers. A transparent layer 120 is formed on the main substrate 110 by heat oxidation or reactive sputtering deposition method. A material of the transparent layer 120 is silicon dioxide (SiO₂). The transparent layer 120 has a thickness in the range from 5 to 20 nanometers.

A reflective layer 130 is deposited on the transparent layer 120. A material of the reflective layer 130 is metal alloy, such as AuX, AlY or AgZ, wherein X represents Be, Li, Ag or Cu, Y represents Cu, Be or Mg, Z represents Be, Li or Al. The reflective layer 130 has a thickness in the range from 10 to 200 nanometers, preferable 20 to 50 nanometers. Reflectivity of the reflective layer 130 is above 90 percent. The reflective layer 130 is deposited by reactive direct current sputtering or reactive frequency sputtering method.

A joint layer 140 is deposited on the reflective layer 130 by reactive direct current sputtering or reactive frequency sputtering method. A material of the joint layer 140 is metal conductor, such as Au, Al or Ag. The joint layer 140 has a thickness in the range from 5 to 20 nanometers.

Referring to FIG. 2C, the assist substrate 170 is turned over to make the LED layer 150 cover the joint layer 140, and then the LED layer 150 is joined with the reflective layer 130 via the joint layer 140 at a joining temperature in the range from 200 to 400 degrees centigrade.

Referring to FIG. 2D, the assist substrate 170 is removed by chemical etching, chemical mechanical polishing, sputter etching or plasma etching method. Thereby the light emitting diode device comprises the main substrate 110, the transparent layer 120, the reflective layer 130, the joint layer 140 and the LED layer 150 stacked in turn from bottom to top.

Referring to FIG. 2E, a diffusing layer 160 is deposited on the LED layer 150, with a thickness in the range from 100 to 500 nanometers. The diffusing layer 160 is scattered with nano silicon dioxide particles. The nano particles have an average particle size in the range from 2 to 20 nanometers, preferable 5 to 10 nanometers. The diffusing layer 160 is configured for scattering light entered thereinto to a wide light distribution angle via multi-scattering. For the light emitting diode device 100, the diffusing layer 160 functions as a light emitting surface, thus a wide light distribution angle is obtained.

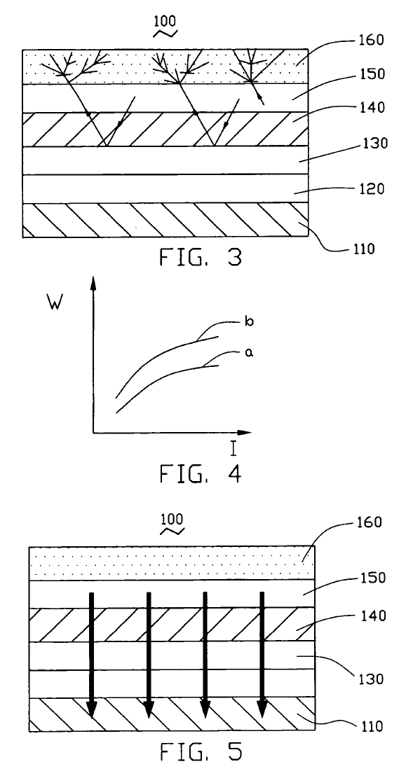

FIG. 3 shows illumination principle of the LED device 100. Arrows shown in FIG. 3 represent light transmission direction. Light emitted from the LED layer 150 has isotropy property. A part of light beams enter the diffusing layer 160 directly, and are scattered by the nano particles in the diffusing layer 160. Then the light beams change their original directions and diffuse to all directions, thus obtain a wide light distribution angle. Other light beams reach the reflective layer 130 and is reflected back into the diffusing layer 160 directly by the reflective layer 130, thus usage efficiency of light beams provided by the light emitting diode device 100 is improved, and illumination thereof is enhanced.

FIG. 4 illustrates a luminance-current contrast chart of light emitting diode device between FIG. 1 and typical LED. Axis of abscissa represents input current labeled as “I”, axis of ordinate represents luminance labeled as “W”. Curve “a” represents light output property of typical LED, while curve “b” represents light output property of light emitting diode device of the preferred embodiment. From the curves we can conclude that the light emitting diode device of the preferred embodiment has higher luminance efficiency.

FIG. 5 shows heat dissipation principle of the LED device 100. Arrows in FIG. 5 represent heat dissipation direction. First of all, since the joint layer 140 and the reflective layer 130 are made of metal materials, both two layers have good heat dissipation property. Thus heat produced by the LED layer 150 can be conducted to the main substrate 110 rapidly. Secondly, since the main substrate 110 is made of silicon, which has better heat conductive property than typical GaAs material. Accordingly, compared with typical LED, the light emitting diode device of the preferred embodiment has better heat dissipation property.

The LED device 100 could be used in all kind of display products, consumer electronic products, communication electronic products and car electronic products.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A light emitting diode device comprising a main substrate, a reflective layer, a joint layer, a light emitting diode layer and a diffusing layer stacked in turn from bottom to top, a material of the main substrate being silicon, a material of the reflective layer being metal alloy, the diffusing layer being scattered with nano silicon dioxide particles.

2. The light emitting diode device as claimed in claim 1, wherein an average particle size of the nano particles is in the range from 2 to 20 nanometers.

3. The light emitting diode device as claimed in claim 1, wherein the diffusing layer has a thickness in the range from 100 to 500 nanometers.

4. The light emitting diode device as claimed in claim 1, wherein a material of the reflective layer is metal alloy AuX, AlY or AgZ, wherein X represents Be, Li, Ag or Cu, Y represents Cu, Be or Mg, Z represents Be, Li or Al.

5. The light emitting diode device as claimed in claim 1, wherein the reflective layer has a thickness in the range from 10 to 200 nanometers.

6. The light emitting diode device as claimed in claim 1, wherein a material of the joint layer is Au, Al or Ag.

7. The light emitting diode device as claimed in claim 1, wherein the joint layer has a thickness in the range from 5 to 20 nanometers.

8. The light emitting diode device as claimed in claim 1, further comprising a transparent layer sandwiched between the main substrate and the reflective layer, the transparent layer comprising a material of silicon dioxide.

9. The light emitting diode device as claimed in claim 8, wherein the transparent layer has a thickness in the range from 5 to 20 nanometers.

10. A method for manufacturing light emitting diode device comprising the following steps:
providing an assist substrate and a main substrate, a material of the main substrate being silicon;
forming a light emitting diode layer on the assist substrate;
forming a reflective layer on the main substrate, the reflective layer comprising a material of metal alloy;
forming a joint layer on the reflective layer;
joining the reflective layer and the light emitting diode layer together via the joint layer;
removing the assist substrate; and
depositing a diffusing layer on the light emitting diode layer, the diffusing layer being scattered with nano silicon dioxide particles.

11. The light emitting diode device as claimed in claim 10, wherein a material of the assist substrate is III-V group compound semiconductor in Periodical Table of Elements.

12. The light emitting diode device as claimed in claim 10, wherein the reflective layer and/or the joint layer are/is formed by reactive direct current sputtering or reactive frequency sputtering method.

13. The light emitting diode device as claimed in claim 10, wherein the light emitting diode layer is formed by spin coating, uniform coating, pre-coating or chemical vapor depositing method.

14. The light emitting diode device as claimed in claim 10, wherein a joining temperature of the joining step is in the range from 200 to 400 degrees centigrade.

15. The light emitting diode device as claimed in claim 10, wherein the assist substrate is removed by chemical etching, chemical mechanical polishing, sputter etching or plasma etching method.

16. The light emitting diode device as claimed in claim 10, further comprising a step of forming a transparent layer on the main substrate before forming the reflective layer.

17. The light emitting diode device as claimed in claim 16, wherein the transparent layer is formed by heat oxidation or reactive sputtering deposition method.
